(19) United States
(12) Patent Application Publication
(10) Pub. No.: US 2025/0289963 A1
(43) Pub. Date: Sep. 18, 2025

(54) SOLIDS-REPELLANT, PATHOGEN-RESISTANT HYDROPHOBIC COATINGS

(71) Applicant: UNIVERSITY OF CENTRAL FLORIDA RESEARCH FOUNDATION, INC., Orlando, FL (US)

(72) Inventors: Kausik Mukhopadhyay, Orlando, FL (US); Pritha Sarkar, Orlando, FL (US)

(21) Appl. No.: 19/032,825

(22) Filed: Jan. 21, 2025

Related U.S. Application Data
(60) Provisional application No. 63/566,723, filed on Mar. 18, 2024.

(51) Int. Cl. C09D 5/16; C09D 5/24; C09D 7/63; C09D 165/00

(52) U.S. Cl. CPC C09D 5/1625; C09D 5/1637; C09D 5/24; C09D 7/63; C09D 165/00

(57) ABSTRACT

Disclosed is a coating composition that includes at least one silane or functionalized silane, and at least one electroactive or electroconductive polymer, and optionally a solvent. In particular, the coating composition comprises a mixture of octadecyltrichlorosilane and poly(3,4-ethylenedioxythiophene):polystyrene sulfonate.

### GOVERNMENT FUNDING SUPPORT

This invention was made with government support under grant no. FSGC-NASA grant (1627-7A02)-NASA 80NSSC20M0093, awarded by the National Aeronautical and Space Administration. The government has certain rights in the invention.

### BACKGROUND

### 1. Field of the Disclosure

The invention relates to the general field of protective coatings. In particular, the coatings are electrically conductive and hydrophobic to produce a surface with self-cleaning properties. These coatings are useful for products in the fields of astronautics and aerospace, spacecraft fabrication, shipping components, lenses and other optical devices, hydrophobic fabrics, pathogen and dust resistant surfaces and gear, biosafe superhydrophobic coatings, dust and sandstorm repellency. water marbles, self-cleaning and anti-fouling surfaces, solar panels, adventure sports (such as bicycling, motorcycling, speed boating), anti-fingerprint coatings, automotive industry, and the like.

### 2. Background of the Disclosure

The harsh conditions of space lead to the accumulation of dust, especially lunar dust, on spacecraft surfaces, which has a negative impact on their performance and longevity. The surface of the moon is covered by lunar dust, a component of lunar regolith that comprises particle sizes less than 20 μm. Because of its fine texture, rough edges, and electrostatic charge, lunar dust tends to adhere to and coat any surface it comes into contact with easily. This poses a known risk to the proper functioning of electronic and mechanical equipment that is used on the lunar surface. Other solid debris, and airborne particulates (aerosols) can penetrate, accumulate, and transport through porous and non-porous surfaces as well, posing significant operational and bodily risks to space planetary explorers. Furthermore, these dangers impact crew equipment such as rovers, space vehicles, and onboard instruments, sensors, thermal switches, solar and electronic panels. The effect is more damaging in the presence of high-speed dust and debris, especially at sub-zero temperatures or temperature gradient cycles, which can cause significant mechanical damage and considerable economic losses. According to the NASA Glenn Research Center, the accumulation of dust on thermal control surfaces can increase their temperature by up to 50° C., leading to thermal stress and potential damage to the spacecraft. Dust accumulation on camera lenses can degrade their image quality and reduce the accuracy of scientific measurements.

Protective coatings currently available in the commercial or niche market have several shortcomings, including durability, inability to repel low surface tension liquids, solid (ice/aerosols) adhesion, low breathability of coated fabrics, excess weight, and use of environmentally harmful compounds that may pose unknown exposure in the lunar and Martian atmospheres, for example. Aside from mechanical damage, the economic loss amounts to millions of dollars in damages for every mission. These statistics highlight the importance of developing effective dust-repellent coatings for spacecraft surfaces. By reducing the accumulation of dust on spacecraft surfaces, these coatings can improve the performance, efficiency, and longevity of spacecraft, reducing the need for frequent cleaning and maintenance.

### SUMMARY

Thus, there exists a need in the art for coating materials that effectively repel dust and otherwise protect a variety of surfaces from environmental factors. In particular embodiments, the present invention relates to a coating composition comprised of silanes, an electroactive or electroconductive species or compounds including polymers, solvents and optional additives such as inorganic materials.

In a particular embodiment, provided is a coating comprising poly(3,4-ethylenedioxythiophene):polystyrene sulfonate and octadecyltrichlorosilane.

Approaches to coat porous and non-porous substrates include spin coating, spray coating, vapor deposition and dip coating the coating composition. According to another embodiment, provided is an object, optionally comprised of both porous and non-porous substrates, coated with a coating composition described herein.

In a further embodiment, provided herein is method of protecting the surface of an object comprising coating a surface of the object with the coating composition described herein. The coating composition may exhibit self-cleaning of the surfaces for low- and high-tension liquids, charged or neutral solid particulates, including dusts. The coating may also exhibit optical clarity, transparency, UV-resistance upon exposure, dent-repellency upon mechanical impact and chemical resiliency upon contact with chemicals and solvents.

### BRIEF SUMMARY OF THE DRAWINGS

Certain embodiments are illustrated by way of example, and not by way of limitation, in the figures of the accompanying drawings.

FIG. 1 is a diagrammatic chart showing the steps for producing coatings according to the invention.

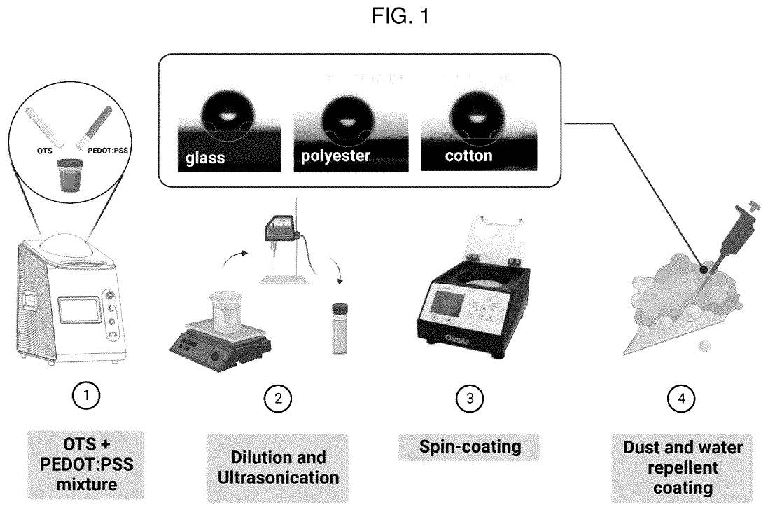

FIG. 2 is a photograph of two glass slides, coated and not coated as indicated, with OTS+PEDOT:PSS coating mixture.

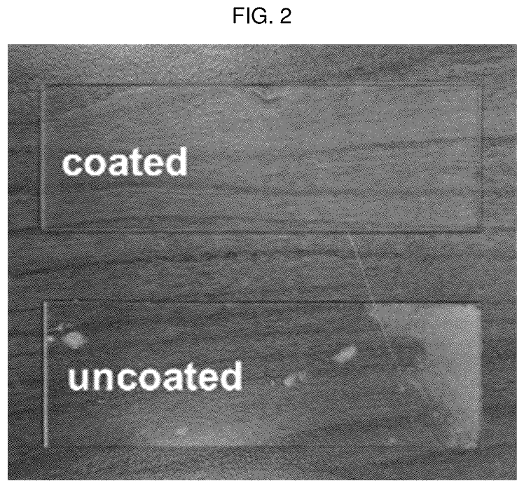

### DETAILED DESCRIPTION

### Definitions

Unless defined otherwise, all technical and scientific terms used herein have the same meaning as commonly understood by one of ordinary skill in the art. Although various methods and materials similar or equivalent to those described herein can be used in the practice or testing of the present invention, suitable methods and materials are described below. However, the skilled artisan understands that the methods and materials used and described are examples and may not be the only ones suitable for use in the invention. Moreover, as measurements are subject to inherent variability, any temperature, weight, volume, time interval, pH, salinity, molarity or molality, range, concentration and any other measurements, quantities or numerical expressions given herein are intended to be approximate and not exact or critical figures unless expressly stated to the contrary.

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than a restrictive sense. Throughout this specification and the claims, unless the context requires otherwise, the word “comprise” and its variations, such as “comprises” and “comprising,” will be understood to imply the inclusion of a stated item, element or step or group of items, elements or steps but not the exclusion of any other item, element or step or group of items, elements or steps. Furthermore, the indefinite article “a” or “an” is meant to indicate one or more of the item, element or steps modified by the article.

As used herein, the term “about” means plus or minus 20 percent of the recited value, so that, for example, “about 0.125” means 0.125±0.025, and “about 1.0” means 1.0±0.2. Notwithstanding that the numerical ranges and parameters setting forth the broad scope of the invention are approximations, the numerical values set forth in specific non-limiting examples are reported as precisely as possible. Any numerical value, however, inherently contains certain errors necessarily resulting from the standard deviation found in their respective testing measurements at the time of this writing. Furthermore, unless otherwise clear from the context, a numerical value presented herein has an implied precision given by the least significant digit. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 4.

### Exemplary Embodiments

Conductive surfaces can reduce dust accumulation through electrostatic discharge. When two objects with unlike charges come into contact, an electric current can flow between them, resulting in a discharge of static electricity. In the context of dust accumulation, when a surface is charged, it can attract and hold onto dust particles, causing a buildup of dust over time. However, if the surface is conductive, it can discharge this static electricity, preventing the buildup of a charge and the resulting adhesion of dust particles. Conductive surfaces can also help to mitigate the effects of triboelectric charging, which occurs when two materials come into contact and exchange charges. This can occur when surfaces on a moving spacecraft encounter dust particles and other materials. By providing a conductive path, any charge buildup can be quickly dissipated, reducing the accumulation of dust and risk of damage to spacecraft surfaces. It has been reported that conductive surfaces can help to reduce dust accumulation by providing a pathway for the dissipation of static charges, which is particularly important in environments where triboelectric charging is common, such as the space environment.

Capillary forces also play a significant role in dust repellency by affecting the adhesion of dust particles to surfaces. They are the result of the intermolecular interactions between a liquid and a solid surface, which can cause the liquid to be drawn up or adhere to the surface. In the context of dust repellency, capillary forces can cause liquid films to form on surfaces, which can attract and hold onto dust particles. However, if the surface is engineered to repel the liquid, the capillary forces can be reduced, preventing the formation of liquid films and reducing the adhesion of dust particles. In addition to reducing the adhesion of dust particles, capillary forces can also affect the self-cleaning properties of surfaces. If the capillary forces are too strong, the liquid may not be able to easily roll off the surface, leading to the accumulation of dirt and debris. However, if the capillary forces are appropriately balanced, the liquid can easily roll off the surface, taking any dust particles with it and resulting in a self-cleaning effect.

Poly(3,4-ethylenedioxythiophene):polystyrene sulfonate (PEDOT:PSS) is a polymer mixture used in designing conductive polymer systems and coatings. Its solubility in water and high conductivity makes it a versatile material for fabricating various kinds of devices and coatings. However, its high hydrophilicity and its tendency to break apart in the presence of water limit its scope in aqueous environments and make PEDOT:PSS coatings difficult to clean and reuse.

This specification presents an approach to developing new dust-repellant hydrophobic coatings using a combination of silanes such as octadecyltrichlorosilane (OTS) and PEDOT:PSS. Silanes are commonly used materials in the fabrication of (super) hydrophobic coatings by the self-assembly of monolayers or micellar formation. OTS has a long chain structure and is a fluorine-free composition, thereby reducing environmental hazards. Due to strong networks of hydrophobic-hydrophilic interactions in OTS/PEDOT:PSS mixtures, rapid gelation can be achieved, aiding in the formation of a versatile coating solution that can be used on a number of substrate materials, including glass, metals, fabric, polymers etc.

Surfaces coated with the compositions according to this invention are both hydrophobic and dust-repellant. It has fair transparency and is water-resistant. Furthermore, the coating can be made multifunctional by doping with additional functional components to impart antibacterial and antifungal, or other properties. Hydrophobic modifications, surface functionalization, and surface roughness modifications, for example, can produce a surface with low contact angle hysteresis for easy roll-off and self-cleaning properties. This technology will find particularly beneficial uses in the aerospace industry and solar energy industry where dust-repellant transparent coatings are in high demand.

The formulations according to this invention are based on one or more silanes or functionalized silanes, PEDOT:PSS, with one or more additional fillers, one or more inorganics, or any combination thereof. The silane(s) optionally can be functionalized with suitable end groups for better crosslinking and/or to impart certain beneficial properties. Examples of functionalized silanes include silanes with a functional group on the organic side chain such as monoamine-functionalized silanes (trialkoxy, dialkoxy, monoalkoxy), diamine-functionalized silanes (trialkoxy, dialkoxy, monoalkoxy), triamine-functionalized silanes, sec-amine-functionalized silanes, tert-amine-functionalized silanes, quat-amine-functionalized silanes, dipodal-amine functionalized silanes, anhydride-functionalized silanes, acrylate- and methacrylate-functionalized silanes (trialkoxy, dialkoxy, monoalkoxy), epoxy-functionalized silanes (trialkoxy, dialkoxy, monoalkoxy), halogen-functionalized silanes (trialkoxy, dialkoxy, monoalkoxy), isocyanate-functionalized and masked-isocyanate-functionalized silanes, phosphate-functionalized silanes, sulphur-functionalized silanes, vinyl- and olefin-functionalized silanes (trialkoxy, dialkoxy, monoalkoxy) and trimethoxysilylpropyl-modified polyethylenimins.

The coating compositions can be deposited onto a substrate by any suitable method of choice, including but not limited to spin coating, dip coating, spray coating, sputter coating, electrospinning, and the like. Chemicals and additional substituents can be incorporated during the process with any suitable chronology, with or without solvents of choice, such as water, hexanes, alcohols, acetone, and other organic solvents. In a more specific embodiment, a solvent includes but is not limited to, a solvent selected from aliphatic alcohols, aliphatic ketones, aliphatic carboxylic esters, aliphatic carboxylic amides, aromatic hydrocarbons, aliphatic hydrocarbons, acetonitrile, aliphatic sulfoxides, water, and mixtures thereof.

The surface coating compositions of the invention include but are not limited to: (1) dust-repellant coatings for wearable fabrics and optical devices; (2) (super) hydrophobic or (super) oleophobic/(super) omniphobic coatings for wearable fabrics and optical devices; (3) (super) hydrophobic or (super) oleophobic/(super) omniphobic and dust-repellant coatings for pipelines and related applications; (4) coating compositions and methods that are economical and biofriendly; (5) pathogen-resistant coatings; (6) methods for introducing bioactive agents into the coating compositions for applications in medicine and healthcare; (7) the ability to produce a patterned surface for low contact angle hysteresis; and (8) the ability to add hydrophobic modifications, surface functionalization, and surface roughness modifications to produce low contact angle hysteresis for easy roll off and self-cleaning properties on the surface.

Some of the advantages of the various coatings according to the invention therefore include dust-repellency, transparency, UV-resistance, biocompatibility, reduced cost, case of fabrication, case of use, usefulness on a wide range of substrates, and the ability to produce low contact angle hysteresis. The formulations allow the user to produce coating compositions that have the combination of characteristics needed for any particular application. Thus, the inventive coatings can be applied to a variety of substrates in numerous industries. Any object can be coated using the compositions of the invention where it is desirable to introduce a surface quality that protects and/or lengthens the useful life of the object. The coatings of the invention are most useful in environments where dust, pathogens, biofouling, fingerprints, weather events, or other circumstances can affect the surfaces, for example camera lenses and other optical devices, aerospace applications, medical and surgical applications, energy applications (such as solar panels and wind turbines, oil rigs, and other equipment), automotive and related industries (such as boating, motorcycles, bicycles, and the like), foul weather gear, outdoor sports equipment, home and mobile home applications, and the like. In general, the invention can be used on any equipment or surface where protection from the environment is desirable, for example dust, biofouling, ash, clean room use, kitchens and other cooking environments, and the like.

The coatings according to the invention take advantage of the effects of dynamic contact angles and contact angle hysteresis values to determine super-repellent behavior of the coated surfaces, as well as static contact angles. These coating also have an advantage over the prior art in that they can be water-resistant and hydrophobic and can serve the dual purposes of pathogen-resistance and dust repellency. In particular, these coatings can effectively repel sub-nanometer scale to millimeter range particulates from the surface.

### EXAMPLES

### Example 1: Composition Formulation

OTS is added to PEDTO:PSS-Water suspension (100 mL OTS in 1000 mL PEDOT-PSS-Water solution) and speed mixed for few minutes at 2500 rpm. The mixture was ultrasonicated with hexane solvent. The solution is then spin coated onto substrates such as, cotton, glass, polyester etc. to have homogenous coating. Once dried, the coating surfaces are tested with dirt, dusts, silica etc. at low and high temperatures, ranging from −40 to 150° C.

### REFERENCES

All references listed below and throughout the specification are hereby incorporated by reference in their entirety.
1. Zhang, L., Zhou, A. G., Sun, B. R. et al. Functional and versatile superhydrophobic coatings via stoichiometric silanization. Nat Commun 12, 982 (2021). doi.org/10.1038/s41467-021-21219-y
2. Wang, L.; Liu, M.; Wu, Y.; Zheng, H. Progress in Studies of Surface Nanotextures and Coatings with Nanomaterials on Glass for Anti-Dust Functionality. Nanomaterials 2022, 12, 3677. doi.org/10.3390/nano12203677
3. Håkansson, A., Han, S., Wang, S., Lu, J., Braun, S., Fahlman, M., Berggren, M., Crispin, X. and Fabiano, S. (2017), Effect of (3-glycidyloxypropyl) trimethoxysilane (GOPS) on the electrical properties of PEDOT:PSS films. J. Polym. Sci. Part B: Polym. Phys., 55:814-820. doi.org/10.1002/polb.24331

1. A coating composition comprising at least one silane or functionalized silane, and at least one electroactive or electroconductive polymer, and optionally a solvent.

2. The coating composition of claim 1, wherein the at least one silane or functionalized silane comprises octadecyltrichlorosilane.

3. The coating composition of claim 1, wherein the at least one electroactive or electroconductive polymer comprises poly(3,4-ethylenedioxythiophene):polystyrene sulfonate.

4. The coating composition of claim 1, applied as a coating on a surface, wherein the coating exhibits self-cleaning of the surface for low- and high-tension liquids, charged or neutral solid particulates.

5. A method of protecting the surface of an object comprising coating the surface of the object with the coating composition of claim 1.

6. The method of claim 5, wherein coating comprises spin coating, spray coating, vapor deposition or dip coating.

7. A coated object produced by the method of claim 5.

8. The coated object of claim 7, wherein the coated object comprises a coating that exhibits one or more of optical clarity, transparency, UV-resistance upon exposure, dent-repellency upon mechanical impact and chemical resiliency upon contact with chemicals and solvents.

9. A method of coating an object, the method comprising: adding OTS to PEDTO:PSS-Water suspension (between 1-20% OTS in PEDOT-PSS-Water solution v/v) to form a mixture and speed mixing the mixture, optionally for about 1-10 minutes at about 2500 rpm; following speed mixing, optionally sonicating the mixture a with hexane solvent; and coating the mixture onto a surface of an object.

10. The method of claim 9, wherein the object comprises cotton, glass, polyester etc. and where coating comprises produces a homogenous coating.

11. The method of claim 9, wherein coating comprises spin coating, spray coating, vapor deposition or dip coating.
